(19) United States
(12) Patent Application Publication
(10) Pub. No.: US 2004/0231586 A1
(43) Pub. Date: Nov. 25, 2004

(54) Method and device for mixing two reactant gases

(76) Inventors: Jacques Dugue, Montigny le Bretonneux (FR); Fabien Lilly, Chaville (FR)

Correspondence Address: AIR LIQUIDE, 2700 POST OAK BOULEVARD, SUITE 1800, HOUSTON, TX, 77056, US

(21) Appl. No.: 10/489,629

(22) PCT Filed: Sep. 9, 2002
(86) PCT No.: PCT/FR02/03055

(30) Foreign Application Priority Data
Sep. 19, 2001 (FR) 01/12101

(51) Int. Cl. C23C 16/00

(52) U.S. Cl. 118/715

(57) ABSTRACT

The invention concerns a method for mixing at least two reactant gases capable of reacting together in a mixer, wherein the retention time of the gases in the mixer is not more than the chemical reaction time of the gases to be mixed, and the standard deviation of retention time distribution (e) represents not more than 20 % of the average retention time (tₘ) of the retention time distribution. Said mixer comprises a first divergent truncated part (2) and a second straight cylindrical part (3). An orifice (4) located at the end of the first part enables axial injection of at least one gas. Orifices (5) are drilled in the wall of the first part for jet-type injection of the or other gases in the main flow.

The invention relates to a process for mixing potentially inflammable reactive gases.

For various chemical processes involving several reactive gases, the prior mixing of these reactive gases may be recommended before they are introduced into the chemical process for which they are intended. However, on carrying out the prior mixing of the reactive gases, risks connected to the reactivity of the gases may become apparent. There are methods for determining the risk of inflammability from mixing at least two reactive gases and for determining the program for injecting gases by taking into account the change in the nature of the inflammability problem, it is also necessary that the final mixture be of good quality, that is to say homogeneous.

The invention therefore relates to a process for mixing potentially inflammable reactive gases making it possible to obtain excellent homogeneity of the mixture for the process for which it is intended, while at the same time preventing the development of a reaction in the mixer.

It is possible to identify several types of mixers. Mixing operations are most often carried out using static mixers. These have a unit which creates a pressure drop when the gases to be mixed flow in contact with this unit, which mixes the gases. These mixers are very efficient but also very bulky. They cannot easily be adapted to plant already in existence, as would be necessary for debottlenecking. Furthermore, they may constitute a risk of plugging or of particle traps. The presence of catalyst particles has already been the cause of accidents and explosions, in particular in the manufacture of nitric acid. Since the mixing mechanisms are somewhat inaccessible inside the mixer, in general this type of equipment is not used when the mixture to be produced is very reactive since the distribution of residence times in such mixers is difficult to identify.

Mixers with cross-flow jets are also used, such as the one described in Application FR-A-2 665 088: this involves a radial gas injector with a swirling motion, which can be used for example for superoxygenation operations in fluid catalytic crackers (or FCCs), catalytic oxidations or furnaces (metallurgy, glass or cement). These mixers are very efficient for obtaining a homogenous mixture over a short distance. However, they are limited by the amounts of gas that it is possible to mix and in their flexibility with respect to gas flows. This type of mixer makes it possible to obtain a homogeneous macroscopic mixture, but in some cases it is possible to observe fluid recirculation regions behind the plume of the jets (quasi wake) or behind the injectors (trail), which could increase the local residence times which may cause spontaneous ignition.

There are also mixers with coaxial jets based on the principle of creating many small jets coaxial with the primary stream. They comprise many injectors of the “rake”-type injecting a highly combustible gas into the air or an oxidizer to limit the risk of ignition (or vice-versa). This type of injector is found in the process for synthesizing ethylene oxide (oxygen injection) or maleic anhydride (butane injection). These mixers are somewhat inflexible and bulky (presence of a long bundle of small tubes). Because of the coaxial jets, the mixing is predominantly diffusional thereby downgrading the performance since it creates a broad contact area between the reactive gases, where the mixing takes place mainly by diffusion (slower mixing).

The aim of the present invention is to provide a process for mixing two potentially inflammable reactive gases making it possible to obtain a homogeneous mixture in a time less than the chemical reaction time of the two gases.

Another aim is to provide a mixer capable of implementing this process.

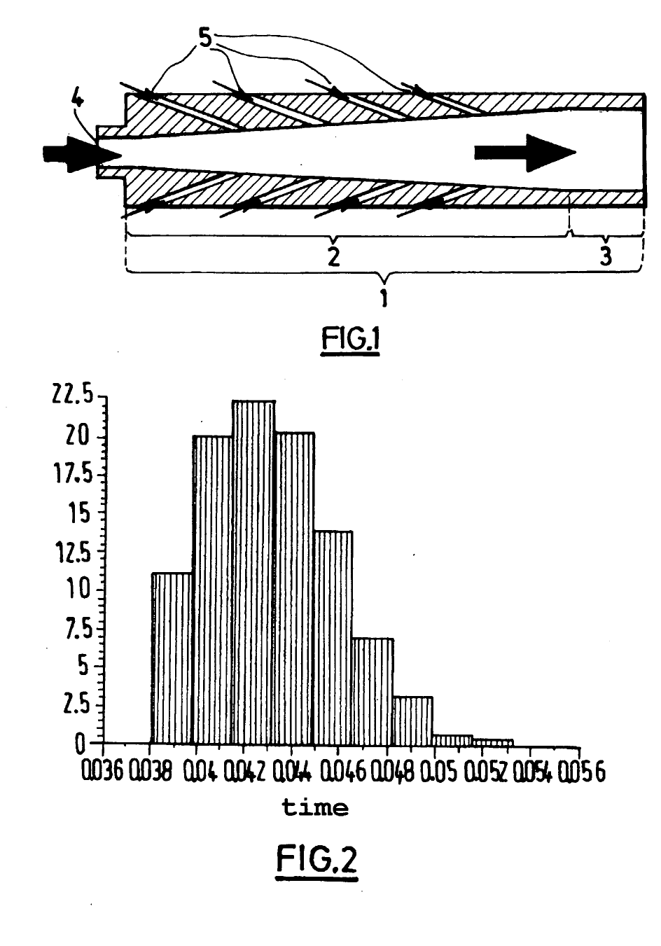

The characteristics and advantages of the invention will become apparent on reading the following description. Embodiments of the invention are given by way of non-limiting example, illustrated by FIG. 1 which is a schematic view of a device according to the invention and by FIG. 2 which is an example of a residence time distribution obtained by using the device of FIG. 1.

First of all, the invention relates to a process for mixing at least two gases capable of reacting together in a mixer, in which:

the mean residence time (tₘ) of the gases in the mixer is less than or equal to the chemical reaction time of the gases to be mixed, and

the standard deviation of the distribution of residence times (e) represents at most 20%, preferably at most 10%, of the mean residence time (tₘ) of the distribution of residence time.

Complying with these conditions ensures that a homogeneous mixture of the two potentially inflammable gases is obtained without any danger. The chemical reaction time of the gases is defined as the delay in ignition by self-ignition of these gases at the temperature and pressure of the mixture. According to a particular embodiment of the process of the invention, the maximum residence time is less than or equal to the chemical reaction time of the gases to be mixed. This maximum residence time is defined by the following formula: T=3 Xe+tₘ, e representing the width of the gaussian distribution of residence times and tₘ the mean residence time of the distribution. This maximum residence time is representative of the residence time for virtually the whole stream (99.8% of the stream).

A residence time distribution of this sort can be controlled by the choice of the mixer geometry and of the velocities and/or flow rates of the gases to be mixed. Thus, in order to implement the aforementioned process, the invention proposes to use a mixer having the following geometry:

a first part of divergent frustoconical shape,

a second cylindrical part placed in the extension of the first part and having the same axis of symmetry, called the axis of the mixer,

an orifice located at the end of the first part and allowing the axial injection of at least one gas so as to form an axial stream in the mixer, called the primary stream,

orifices drilled in the wall of the first part and allowing the injection in the form of jets of the other gas or gases into the primary stream, the said orifices being oriented towards the centre of the mixer in the direction of injection of the gases into the mixer and at an angle β between 20° and 70° to the axis of the device.

The first part of the mixer makes it possible to control the distribution of residence time of the gases while the second part makes it possible to complete the mixing of the gases up to the characteristics imposed by the downstream process, such as the degree of homogeneity or a dispersion of particles, for example. More specifically, the invention relates to this type of device consisting of two parts placed in the extension one of the other and engaging one with the other. The first part is of divergent frustoconical shape. The gases are introduced from that side of the cone body which has the smaller-diameter cross section so that they head for the other side of the cone, towards the second part of the mixer. The half-angle γ at the apex of the cone formed by the first part of the mixer is generally at most 10°, preferably between 2° and 8°, even more preferably between 4° and 6°. The second part is placed in the extension of the first divergent part, therefore on that side of the cone body which has the larger-diameter cross section. This second part has the shape of a cylinder centred on the same axis of symmetry as the first frustoconical part. The second part engages with the first part, but the diameter of the cylinder is the same as that of the widest end of the cone. The length of the second cylindrical part is preferably between 1D and 100D, preferably between 10D and 70D, even more preferably between 20D and 50D, where D is the diameter of the cylinder formed by this second part. This length is generally a function of the degree of homogeneity required of the mixture; it must also comply with conditions relating to the residence time distribution. The gases to be mixed are injected via orifices which are all located in the first part of the mixing device. Two types of orifices can be distinguished. First of all, the device comprises an orifice located at that end of the first part of the mixer which has the smaller-diameter cross section. The orifice has a shape such that it allows the axial injection of at least one gas so as to form a stream parallel to the axis of the mixer. The device then comprises orifices drilled in the wall of the first part of the mixer. Preferably, these orifices are distributed uniformly over the wall of the cone body of the first part. In general, they all have the same shape, often round. Preferably, they all have the same diameter. According to a preferred variant, they are distributed in the form of at least two rings, the said rings corresponding to cross sections of the cone body. Over the same ring, the orifices are generally placed uniformly at the same distance one from the other; this distance is preferably at least twice the diameter of these orifices. Preferably, a mixer having the greatest possible number of rows of orifice rings in the first part of the mixer is used. It is preferable that, for two adjacent rings, the holes of one are offset with respect to the other. For each of these orifices drilled in the wall of the first part of the mixer, the central axis of this orifice is oriented towards the centre of the mixer in the direction in which the gases are injected into the mixer at an angle β between 20° and 70° preferably between 20° and 60°. Preferably, all these orifices have the same angle of orientation. These orifices may be configured so as to give a radial effect with a swirling motion to the gas or gases coming from the said orifices. Preferably, this effect is not implemented for the primary stream. The diameters of the orifices are generally fixed according to the ratios of the velocities of the gases which are injected into the mixer: thus they can make it possible to determine the velocity of the gas injected so that the velocity is greater than that of the gas mixture flowing in the frustoconical section.

More specifically, the invention relates to the mixing device in which all the orifices drilled in the wall of the first part of the device have the same cross-sectional shape and the same diameter.

The mixer described above is particularly suitable for gas mixtures whose ratio V₂²/V₁² is between 1 and 2, and preferably between 1 and 1.5, where:

V₁ is the velocity of the gas or gases injected via the orifice located at the end of the first part,

V₂ is the velocity of the gas or gases injected via the orifices drilled in the wall of the first part of the mixer.

The gaseous mixtures of methane and oxygenated gases may particularly be handled by this mixer; methane is injected into the orifice located at the end of the first part and an oxygenated gas is injected into the orifices drilled in the wall of the first part.

FIG. 1 illustrates a section of a mixing device according to the invention. The mixer (1) has a first part of divergent frustoconical shape (2) (half-angle at the apex=6°, length=35 mm) and a second right-hand cylindrical part (3) placed in the extension of the first part (diameter=34 mm, length=1190 mm). An orifice (4) located at the end of the first part makes it possible to inject axially at least one gas. Orifices (5) (diameter=2.5 mm) are drilled in the wall of the first part thereby allowing the injection in the form of jets of another gas or other gases into the primary stream. They are distributed in the form of four rings each with 16 orifices, the axis of each ring being parallel to the axis of the mixer. These orifices are oriented towards the centre of the mixer in the direction in which the gases are injected into the mixer at an angle of 50° with respect to the axis of the mixer.

### EXAMPLE

The mixer defined by FIG. 1 is used to mix CH₄ and an oxygen/carbon dioxide premixture. CH₄ is introduced with a velocity of 46 m/s and the oxygen/carbon dioxide premixture is introduced with a velocity of 54 m/s. The chemical reaction time is 400 ms.

FIG. 2 shows the residence time distribution obtained during this mixing by monitoring particles in the stream. The following results are obtained:

the mean residence time of the gases in the mixer in order to reach a degree of homogeneity of the coefficient of variation (CV) of 5% is only 27 ms, therefore less than the chemical reaction time of the gases to be mixed, which is 400 ms (result obtained by statistical calculations on the distribution of the CH₄ concentrations over each cross section of the mixer),

the standard deviation of the distribution of residence times (e) is 3.5 ms, that is less than 20% of the mean residence time (tₘ) of the distribution of residence times,

the maximum residence time T=3 Xe+tₘ is 37.5 ms, therefore is less than the chemical time of 400 ms by a factor of 10.

It is verified that a homogeneous mixture is obtained at the output of the mixer by ensuring that the homogeneity attained at 5% is compatible with the desired process use.

1-12. (canceled)

13. Process for mixing at least two gases capable of reacting together in a mixer, wherein:
the mean residence time of the gases in the mixer is less than or equal to the chemical reaction time of the gases to be mixed; and
the standard deviation of the distribution of residence times represents at most about 20% of the mean residence time of the distribution of residence times.

14. Process according to claim 13, wherein said standard deviation represents at most about 10%.

15. Process according to claim 13, wherein the maximum residence time is less than or equal to the chemical reaction time of the gases to be mixed.

16. Process according to claim 13, wherein a mixer having the following geometry is used:
a first part of divergent frustoconical shape;
a second cylindrical part placed in the extension of the first part and having the same axis of symmetry, called the axis of the device;
an orifice located at the end of the first part and allowing the axial injection of at least one gas so as to form an axial stream called the primary stream; and
at least two orifices drilled in the wall of the first part and allowing the injection in the form of jets of the other gas or gases into the primary stream, the said orifices being oriented towards the center of the mixer in the direction of injection of the gases in the mixer and at an angle β between about 20° and about 70° to the axis of the device.

17. Device for mixing at least two gases capable of reacting together, comprising:
a first part of divergent frustoconical shape;
a second cylindrical part placed in the extension of the first part and having the same axis of symmetry, called the axis of the device;
an orifice located at the end of the first part and allowing the axial injection of at least one gas so as to form an axial stream called the primary stream; and
orifices drilled in the wall of the first part and allowing the injection in the form of jets of the other gas or gases into the primary stream, said orifices being oriented towards the centre of the mixer in the direction of injection of the gases in the mixer and at an angle β between 20° and 70° to the axis of the device and said orifices being distributed in the form of at least two rings, said rings corresponding to cross sections of the first frustoconical-shaped part.

18. Device according to claim 17, wherein the half-angle y at the apex of the cone formed by the first part is at most about 10°.

19. Device according to claim 17, wherein the length of the second right-hand cylindrical part is between 1 and 100D, where D is the diameter of the cylinder formed by this second part.

20. Device according to claim 17, wherein all the orifices drilled in the wall of the first part have the same cross-sectional shape and the same diameter.

21. Device according to claim 18, wherein the orifices drilled in the wall of the first part are configured so as to give a radial effect with a swirling motion to the gas or gases coming from these orifices.

22. Process for mixing at least two gases capable of reacting together, in which the device according to claim 18 is used.

23. Process according to claim 22, wherein the ratio V₂²/V₁² is between 1 and 2, where:
V₁ is the velocity of the gas or gases injected via the orifice located at the end of the first part; and
V₂ is the velocity of the gas or gases injected via the orifices drilled in the wall of the first part of the mixer.

24. Process according to claim 22, wherein it is implemented in order to mix methane and an oxygenated gas and in that methane is injected into the orifice located at the end of the first part and the oxygenated gas is injected into the orifices drilled in the wall of the first part.

25. A method for mixing at least two gases in a mixer, wherein:
the mean residence time of the gases in the mixer is less than or equal to the chemical reaction time of the gases to be mixed; and
the standard deviation of the distribution of residence times (e) represents at most 20% of the mean residence time (tm) of the distribution of residence times; and
a homogenous mixture of potentially inflammable gases is obtained without a chemical reaction.

26. The method of claim 25, wherein the standard deviation of the residence time represents at most about 10% of the mean residence time required to achieve a homogenous mixture.

27. The method of claim 25, wherein at least one of the gases is reactive.

28. The method of claim 27, wherein at least two one of the gases are reactive.

29. The method of claim 25, wherein the gases comprise methane and oxygen.

30. An apparatus for mixing at least two gases comprising:
a first part of divergent frustoconical shape;
a second part of cylindrical shape, wherein said second part is an extension of said first part, in such a way that said first part and said second part have the same axis of symmetry;
an orifice at the end of said first part, wherein at least one gas is introduced on an axial basis and transverses through the first part and the second part so as to form an axial steam;
at least two orifices, located in the wall of the first part, which allow the introduction of at least one other gas into the axial stream, wherein said orifices are oriented towards said axis of symmetry; and
said at least one other gas to be mixed with the axial stream is introduced to the axial stream at an angle β between about 20° and about 70° to said axis of symmetry.

31. The apparatus of claim 30, further comprising:
a half-angle γ at the apex of the cone formed by said first part is at most 10°; and
the length of said second part is between 1 D and 100 D, wherein D is the diameter of the cylinder formed by said second part.

32. The apparatus of claim 31, wherein said half-angle γ is between about 2° and about 8°.

33. The apparatus of claim 31, wherein said half-angle γ is between about 4° and about 6°.

34. The apparatus of claim 28, further comprising:
a plurality of all the orifices drilled in the wall of the said first part having the same cross-sectional shape and the same diameter; and
a plurality of orifices drilled in the wall of the said first part configured giving a radial effect with a swirling motion to the gas or gases mixing with the primary stream; and
mixing of gases occurs with the introduction of the gas streams directed through the plurality of orifices to the primary stream.

35. The method of claim 25 wherein the ratio V₂²/V₁² is between 1 and 2, where:
V₁ is the velocity of the gas or gases injected via the orifice located at the end of the first part; and
V₂ is the velocity of the gas or gases injected via the orifices drilled in the wall of the second part.
